(19) United States
(12) Patent Application Publication
(10) Pub. No.: US 2011/0267122 A1
(43) Pub. Date: Nov. 3, 2011

(54) ALL-DIGITAL CLOCK DATA RECOVERY DEVICE AND TRANSCEIVER IMPLEMENTED THEREOF

(75) Inventors: Deog Kyoon Jeong, Seoul (KR); Do Hwan Oh, Seoul (KR)

(73) Assignee: GLONET SYSTEMS, INC., Seoul (KR)

(21) Appl. No.: 12/681,838

(22) PCT Filed: Jan. 22, 2009
(86) PCT No.: PCT/KR2009/000321

§ 371 Date: Apr. 6, 2010

(51) Int. Cl. H03K 5/00

(52) U.S. Cl. 327/165

(57) ABSTRACT

The present invention relates to an all-digital clock data recovery (CDR) which is implemented by a digital filter and a digitally controlled oscillator. The CDR of the present invention comprises a phase detector producing a digital sequence of data and a digital sequence of edge by sampling the serial data stream with a clock, a de-serializer transforming the digital sequences of data and edge into n-bit bus, a digitally controlled oscillator (DCO) implemented by a multi-stage chain of inverters having a variable resistance switching matrix wherein the resistance of each element of the variable resistance switching matrix is varied in such a way that the supply current being fed to each inverter is controlled in pursuant to a digital control code, and thereby producing a clock whose oscillation frequency is updated and fed to the phase detector, a digital synthesis control logic circuit generating a thermometer-code-type digital control code out of the n-bit data and n-bit edge from the de-serializer wherein the thermometer-code-type digital control code is fed to the DCO, and a 2-bit direct forward path directly controlling the frequency of the clock being produced by the DCO with an operating speed which is faster than the digital synthesis control logic circuit by n times.

### CROSS REFERENCE TO RELATED APPLICATION

This application claims priority under 35 USC §119 to PCT Application No. PCT/KR2009/000321, filed on Jan. 22, 2009, the contents of which are incorporated herein by reference in their entirety.

### FIELD OF THE INVENTION

The present invention relates to a Clock Data Recovery (CDR) restoring a clock and data from the received data bit stream in the serial data communication, and a transceiver implemented thereof, and more particularly the all-digital circuit technology for implementing the CDR device without any analog part.

### BACKGROUND OF THE INVENTION

Recently, a serial link transceiver tends to be integrated in a single chip due to the boosting utilization of the high-speed serial link which can transmit gigabits per second. The sender transmits only the data stream without a clock to the receiver through the communication channel in the chip-to-chip communication. A clock and data recovery, which extracts a clock and data from the transmitted serial data, is needed for the receiver to process the serial data bits which are transmitted at the rate of gigabit per second.

The state of the art in this field relies on the analog scheme wherein the voltage controlled oscillator (VCO) as well as the charge pump phase-locked loop (CPPLL) is implemented by an analog circuitry.

FIG. 1 is a schematic diagram illustrating the prior-art configuration of the CPPLL which is commonly utilized in the industry. Referring to FIG. 1, we can see that a CDR circuit in accordance with the prior art consists of a phase detector (10), a frequency detector (20), voltage controlled oscillator (30), and a charge pump circuit (40). The phase detector (10) of the CDR circuit of the prior art extracts the phase of the sampled data by sampling the serial data bit stream with a clock, which has been provided by the VCO (30), and thereby detecting the data value and the edge value.

Since the phase lag implies that the clock frequency is slow, the CDR circuit generates the UP signal, which turns on the transistor (42) for pumping up the charge to the capacitor (41) and thereby increasing the capacitor voltage. The frequency of the recovered clock, which is generated by the VCO, is tuned to increase since the voltage applied at the VCO is raised.

To the contrary, if the phase which the phase detector (10) detects at the sampling point is leading, we need to reduce the frequency of the clock. Therefore, the circuit activates the DN signal for the charge pump circuit (40) to pull down the charges of the capacitor (41) in such a way that the voltage at the capacitor falls down.

Thus, the clock data recovery circuit according to the prior art feeds back the output of the VCO (30) and finely tunes the clock by monitoring if the phase of the serial data leads or lags. The frequency detector (20) sets the frequency of the clock to the reference value by locking the feed-back circuit if there exists a significant amount of errors between the frequency of the serial data and the recovered clock frequency at the receiver.

The prior-art clock data recovery utilizing the CPPLL has been implemented either by analogy circuits or by the mixture of analog and digital circuits. Namely, the conventional CDR is implemented by the mixed analog-digital circuits wherein the phase detector(10) and the frequency detector(20) are implemented by digital circuits while the charge pump circuits(40) and the voltage controlled oscillators (30), depicted at the right block of FIG. 1, are implemented by analog circuits.

More recently, the design rule of the semiconductor integrated circuit has been reduced down to sub-100 nanometers as the integration density of the semiconductor integrated circuits increases. Accordingly, the thickness of the oxide film has been reduced down to several nanometers or several tens nanometers in compliance with the scaling law.

Capacitors integrated in the semiconductor integrated circuit are usually implemented with gate oxide layer. If the thickness of the gate oxide film is reduced down to the scale of nanometer, the current leakage problem becomes significant in the capacitors (41) comprising the charge pump circuits (40). Consequently, it is not easy to restore a clock by fine-tuning in the nanometer-scaled integrated circuit since the voltage controlling the voltage controlled oscillator (30) is varied by the leakage current.

Furthermore, since the power supply for the 100 nanometer design rule is less than 1.0 V, it is impossible to implement the current sources (45) for the charge pump circuit (40) in the 100 nanometer-scaled semiconductor integrated circuit.

If the current sources are to be implemented with MOS field-effect transistors, the MOS transistors should be operated in the pinch-off mode. For this mode of operation, we need at least 1.0 V of voltage swing from the power supply line to the ground line. Therefore, we find some difficulties in implementing the analog charge pump circuits in the sub-100 nanometer integrated circuits, which has a constraint in the power supply voltage wherein the power supply voltage should be less than 1.0 V.

### SUMMARY OF THE INVENTION

Accordingly, the goal of the present invention is to provide an all-digital CDR scheme wherein the charge pump circuit and the voltage controlled oscillator, which were the analog parts in the conventional CDR technology, are now implemented with digital circuits.

Another goal of the present invention is to provide a method and configuration architecture implemented thereof for eliminating the jitters due to the quantization errors and for resolving the inherent problem of the sluggish operation of digital filters when the conventional CDR circuitry including the charge pump circuit as well as the voltage controlled oscillator is to be converted into the digital circuitry either via digital filters or via digital circuits.

Additional goal of the present invention is to provide a method and circuit implemented thereof for minimizing the hardware size of the circuit block of the digitally controlled oscillator (DCO), for reducing the generation of glitches, and for equalizing tuning steps in the frequency scale.

The present invention discloses how to implement an all-digital CDR device, and resolves the issues of jitters which are inevitable due to the leakage current in the conventional fine-pitch analog integrated circuits. Accordingly, the present invention makes it possible to operate the CDR circuit even if we have to design an all-digital CDR circuit under the restriction that the power supply voltage should be less than 1.0 V. In addition, the present invention provides a method to resolve a variety of technical issues which we are faced with during the step of designing an all-digital CDR device.

To achieve the aforementioned goals, the CDR device in accordance with the present invention has features in that charge pump circuit is implemented via digital filter circuits while voltage controlled oscillator (VCO) is implemented via digitally controlled oscillator (DCO). The DCO in the present invention comprises a multi-stage inverter chain and a variable-resistor switching matrix between the power supply and each inverter of the chain and adjusts the supply current for each inverter by varying the resistance value of each element of the switching matrix to tune the oscillating frequency.

### BRIEF DESCRIPTION OF THE DRAWINGS

FIG. 1 is a schematic diagram which illustrates the configuration of the conventional CPPLL (Charge Pump Phase-locked Loop) receiver.

FIG. 2 is a schematic diagram which illustrates the configuration of the all-digital clock data recovery (CDR) in accordance with the invention.

FIG. 3 is a schematic diagram which illustrates the configuration of the all-digital CDR in accordance with a preferred embodiment of the present invention.

FIG. 4 is a schematic diagram illustrating the operating principle of the binary-to-segment thermometer (B2T) converter as a constituent for CDR in accordance with the present invention.

FIG. 5 and FIG. 6 are schematic diagrams illustrating the algorithms and implementing method thereof, respectively, for inherently preventing the generation of glitches in accordance with a preferred embodiment of the present invention.

FIG. 7 is a schematic diagram illustrating the insertion of vertical resistors between the rows of the variable resistor switching matrix in an effort to equalize the fluctuation of the resistances in accordance with a preferred embodiment of the present invention.

FIG. 8 is a schematic diagram which illustrates the block constituting the direct forward path of the CDR in accordance with the present invention.

FIG. 9 and FIG. 10 are plots illustrating the experimental results of the frequency tuning when vertical resistors are inserted between the rows of the variable resistor switching matrix in accordance with a preferred embodiment of the present invention.

FIG. 11 is a diagram illustrating the configuration of an integral path comprising a block of the CDR in accordance with a preferred embodiment of the present invention.

FIG. 12 and FIG. 13 are schematic diagrams illustrating a preferred embodiment for restoring a clock by using the CDR in accordance with the present invention.

FIG. 14 is a schematic diagram illustrating the pattern of PRBS (2³¹−1) at the transmission rate of 2.5 GBPS under 1.2 V power supply in accordance with a preferred embodiment of the present invention.

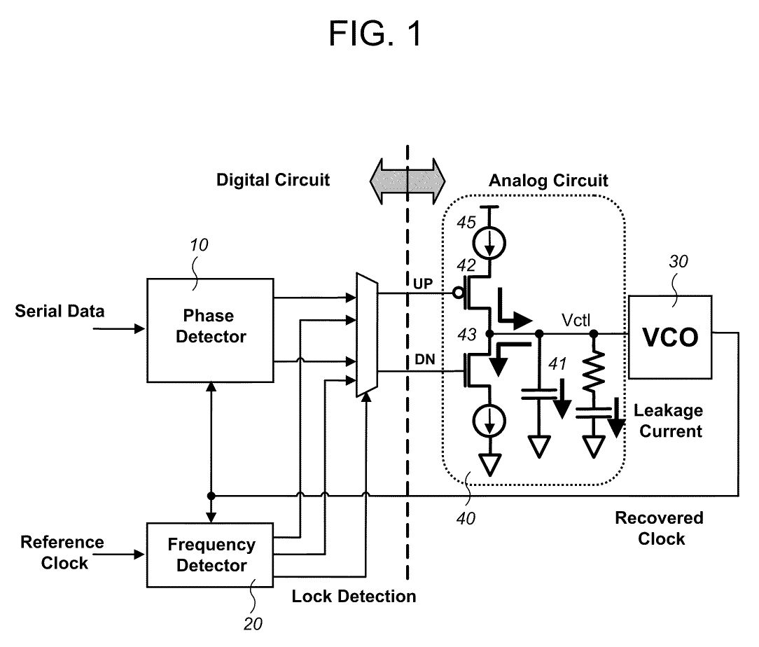

### DETAILED DESCRIPTION OF THE INVENTION

As a preferred embodiment of the present invention, a variable resistance switching matrix is implemented by PMOS transistor arrays wherein the PMOS transistors act as variable resistors since the amount of conducting current is controlled by the input gate voltage. The present invention proposes an approach of inserting vertical resistances between the rows of the switching matrix in order to equalize the frequency tuning steps both at high levels and at low levels. Obviously, the vertical resistance is implemented by a PMOS transistor while the gate is grounded.

In addition, the present invention employs 1^{st} ΣΔ (sigma-delta) modulator to implement the dithering algorithm in an effort to resolve the jitter noise problem which is caused by the quantization errors when comparison is made between digitally controlled oscillator (DCO) and voltage controlled oscillator (VCO) of analog type. For instance, the present invention prevents the generation of quantization errors for a digital signal, for instance, having 10 MSB (most significant bit) bits and additional 7 LSB bits for dithering in order to secure 17 bit resolution power.

Since the chip size may blow up due to the expansion of the hardware block of the control circuit when the digital code for the control of the oscillating frequency of the DCO is binary, the CDR of the present invention tunes the DCO with minimum number of routing lines by employing the segmented thermometer scheme.

The subject matters of the present invention are described in appended claims. The present invention relates to an all-digital clock data recovery (CDR) which is implemented by a digital filter and a digitally controlled oscillator. The CDR of the present invention comprises a phase detector producing a digital sequence of data and a digital sequence of edge by sampling the serial data stream with a clock, a de-serializer transforming the digital sequences of data and edge into n-bit bus, a digitally controlled oscillator (DCO) implemented by a multi-stage chain of inverters having a variable resistance switching matrix wherein the resistance of each element of the variable resistance switching matrix is varied in such a way that the supply current being fed to each inverter is controlled in pursuant to a digital control code, and thereby producing a clock whose oscillation frequency is updated and fed to the phase detector, a digital synthesis control logic circuit generating a thermometer-code-type digital control code out of the n-bit data and n-bit edge from the de-serializer wherein the thermometer-code-type digital control code is fed to the DCO, and a 2-bit direct forward path directly controlling the frequency of the clock being produced by the DCO with an operating speed which is faster than the digital synthesis control logic circuit by n times.

The digital synthesis control logic circuit of the CDR in accordance with the invention comprises an UP/DN signal generator which produces an instruction code in the range of the levels −n˜+n either for the frequency increase or for the frequency decrease from the n-bit data and n-bit edge data which was generated by the de-serializer of the digital synthesis control logic circuits; an IIR digital filter which produces (m+k) bit codes by integrating the UP/DN signals; a 1^{st} sigma-delta modulator which has a resolution power of (m+k) bits and produces m-bit digital code from the uppermost m MSB bits through dithering the lowermost k LSB bits in (m+k) bit codes which are generated by the IIR digital filter; a binary to segment thermometer converter which converts a total of 2^{m} frequency tuning level into 2^{m/2}+(2^{m/2}−1) bit thermometer code which is thereafter fed to the row and column routing wires of the variable resistance switching matrix; and a frequency detector which enforces the reference frequency in digital code when the difference between the clock frequency of the DCO and the reference frequency crosses over the threshold.

Furthermore, the glitch elimination method of the present invention employs a scheme as a preferable embodiment wherein each cell of a first column in the variable resistance switching matrix is set “on” when the cell value of the corresponding row is “1”, while each cell of the row of even numbering is set “on” when the corresponding column code is “1”, and each cell of the row of odd numbering is set “on” when the corresponding column code is “0”.

Further, the variable resistance switching matrix which is a constituent of the DCO in accordance with the present invention comprises 2^{m/2}×2^{m/2} cells for equalizing the frequency tuning steps and additional cells for initializing the oscillation when powered up wherein those cells are implemented by PMOS gate-controlled resistance matrix. More preferably, additional PMOS voltage controlled resistors with gate grounded can be inserted between the rows.

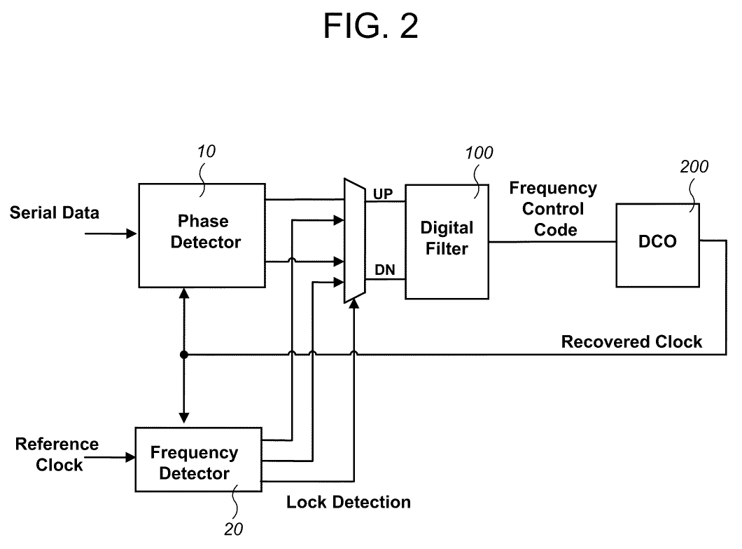

Detailed descriptions will be made on preferred embodiments and constitutional features of the CDR in accordance with the present invention with reference to attached figures from FIG. 2 to FIG. 14.

FIG. 2 is a schematic block diagram illustrating the configuration of the CDR in accordance with the present invention. Referring to FIG. 2, we can see that the CDR of the present invention consists of phase detector (10), frequency detector (20), digital filter (100), and digitally controlled oscillator (DCO, 200) as a preferred embodiment.

However, there are still substantial technical issues that need to be resolved if we want to implement the entire blocks of the CDR as well as the digital filter (100) and DCO (200), as shown in FIG. 2, with digital circuits. Namely, the digitally controlled oscillator (DCO) comprising the CDR in accordance with the invention will suffer from jitters which are inevitably generated during the quantization due to its inherent properties of digital circuits. A DCO with high resolution should be designed if the time uncertainty is to be mitigated.

Furthermore, if the serial data bit stream fed to the phase detector (10) happens to exhibit no up/down change for a while, for example, if either the signal “1” or the signal “0” repeats for several consecutive bits like 11111111000 . . . , the errors are inevitably accumulated in the phase or frequency detection.

Therefore, the ADPLL (all-digital phase-locked loop) CDR in accordance with the present invention also provides a solution to overcome the technical hurdles such as the quantization errors and accumulated errors in phase and frequency detection for making the entire CDR blocks be implemented only with digital circuit.

Moreover, since the operating speed of the digital filter (100), which is a constituent of the CDR according to the present invention, is as slow as a few hundreds of MHz, it is difficult to synchronize the operation of the digital filter with that of the phase detector (10) processing the serial data stream which is transmitted at a rate of gigabit per second. The present invention proposes a solution to overcome the technical difficulties due to slow operation of digital filter circuits when we want to implement the CDR with all-digital circuits.

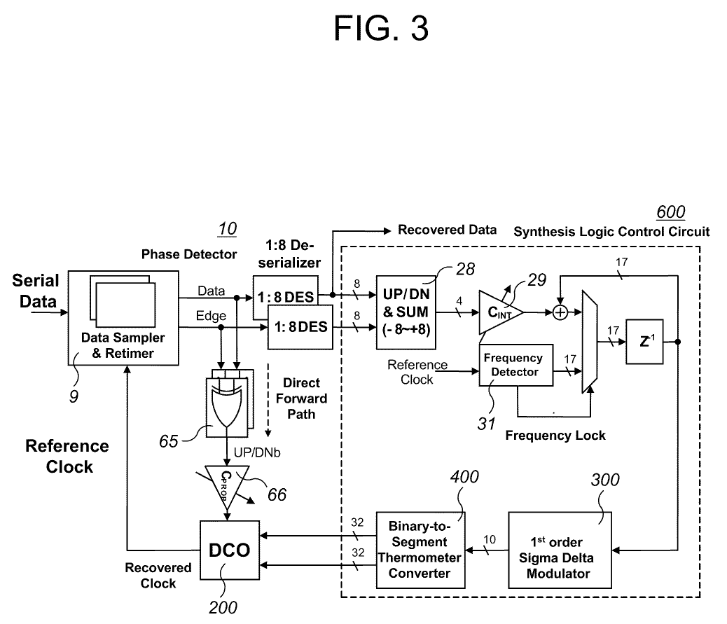

FIG. 3 is a schematic diagram illustrating the configuration of the Clock Data Recovery in accordance with a preferred embodiment of the invention. Referring to FIG. 3, we can see that the constitutional feature of the present invention is that the direct forward path operating at a transmission rate of gigabit per second is separated from the integral path, namely, from the synthesized control logic (600), operating at a rate of a few hundreds of MHz. The 1:8 de-serializer (8) of the synthesized control logic (600) block converts the serial bit stream into 8-bit parallel data bus wherein the clock frequency of the converted 8-bit data bus is 8 times slower than that of the original serial bit stream, which is then delivered to the digital filter logic circuits. Thus, we can help the digital filter circuit accurately keep track of the frequency by slowing down the clock rate by eight times.

FIG. 3 is a schematic diagram illustrating a preferred embodiment in accordance with the present invention wherein 32 bits of thermometer code is generated via de-serializing the data by 1:8 and 10 bits of digital-controlled code is then generated via employing the 7 through to 17 bits for dithering as LSB. However, the scope of the present invention does not necessarily limit the number of bits to this example.

Data sampler & re-timer (9) samples the data and edge and thereafter performs XOR gate(65) operation, which is followed by the integration of the phase information by the integrator (66) for the control of digitally controlled oscillator(DCO; 200). Consequently, data sampler & re-timer (9) effectively loads an appropriate damping factor during the stage of clock recovery. In other words, data sampler & re-timer (9) directly controls the oscillator by detecting the phase information both of the data and of the edges of the serial digital data stream of the gigabit per second rate in the forward path, which enhances the stability of the tuning circuit due to a damping factor effect to the oscillator.

Furthermore, the signal values of the data and the edge, which has been de-serialized to 8-bit bus are fed to the up/down & sum (28) and transformed into 4-bit tracking data according to the level which is divided into sixteen steps (−8 to +8). The O-bit tracking data regarding the phase is now multiplied by the filter coefficient, integrated by the integrator, and then added by the digital integrator (29).

The 17-bit data from the digital integrator (29) is converted to a 10-bit data through the first-order sigma-delta modulator (300). Here, the first-order sigma-delta modulator(300) functions as a dithering device, which resolves the error-accumulation problem when the detector recognize as if there seems to be no phase change for the serial data stream because the data sequence does not go up and down and sticks to the same value in the successive bits.

In accordance with a preferred embodiment of the invention, we can employ the upper 10 bits as representing an integer number while the lower 7 bits represents the decimals for resolving the frequency error-accumulation problem. Namely, the dithering circuit compensates the quantization errors by taking into account the decimals when the serial input data does not change and sticks to the same value in the successive bits such as 11111 . . . 111.

The 10-bit digital signal from the first-order sigma-delta modulator (300) is divided into a couple of 5-bit data via binary-to-segment thermometer convertor and transformed into 32-bit thermometer bus. We can effectively reduce the size of the hardware by segmenting the 10-bit data into two 5-bit data and converting into 32-bit×32-bit thermometer signal.

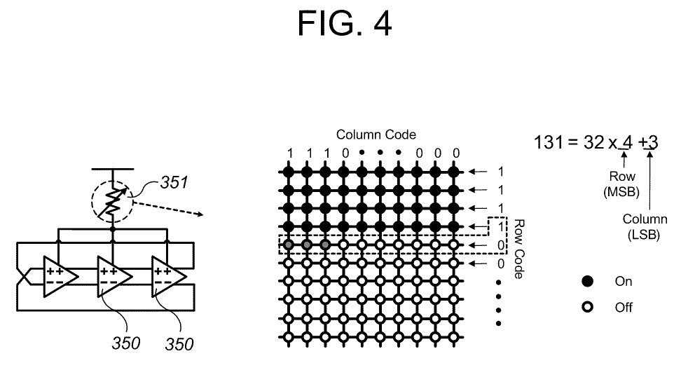

FIG. 4 is a diagram illustrating the operating principle of the binary to segment thermometer converter which comprises the CDR in accordance with the invention. Referring to FIG. 4, we can see a ring oscillator which is constructed by connecting the inverters (350) with a feed-back loop like a chain. The current which is supplied to the inverters (350) of the ring oscillator can be controlled by variable resistors (351) wherein the increase of the supply current due to the reduction of the size of the resistors raises the oscillation frequency while the decrease of the supply current lowers the oscillation frequency of the ring oscillators.

The binary to segment thermometer converter (400) of the present invention transforms the 10-bit bus from the first-order sigma-delta modulator (300), namely 2¹⁰=1024 level information, into a 2⁵×2⁵ switching matrix, namely a 32×32 switching matrix. In other words, the present invention controls the tuning of the oscillation frequency by implementing a 32×32 switching matrix in stead of having a 1023 control lines. For instance, let us suppose that we want to represent 131. Since 131=32×4+3, “4” can be expressed as “1111000 . . . 00” at row as an MSB while “3” can be expressed as “11100 . . . 000” at column as an LSB.

Referring to FIG. 4, we can see that the MSB “4” is placed at row as a 32-bit entry “11100 . . . 000” while the LSB “3” is placed at column as “1110000 . . . 000”. Here, the switching matrix is turned “on” in case when the row value is 1 while the system refers to column value in case when the row value is 0. Further, the switching matrix is turned “ON” in case when the column value is 1 while being turned “OFF” in case when the column value is 0, as shown in FIG. 4. In this manner, a total of 1024 levels can be implemented only by 64 units in terms of the number of hardware, which significantly reduces the hardware volume.

However, we cannot rule out the possibility that a glitch can be produced in the segment thermometer converter according to the switching matrix scheme when the row code changes from 1 to 0 or from 0 to 1. For instance, when the data changes the level 127 (=32×3+31) to 128 (=32×4+0), the MSB of the switching matrix of the segment thermometer (400), which controls the supply current to the DCO (200), crosses over from “11100 . . . 0” to “11110000 . . . 0” while the LSB transfers from “11111 . . . 1” to “000 . . . 0”. In this case, since all the bits goes from 1 to 0, a signal noise or glitch, whatever, can be produced. The present invention proposes a novel scheme for resolving this glitch issue.

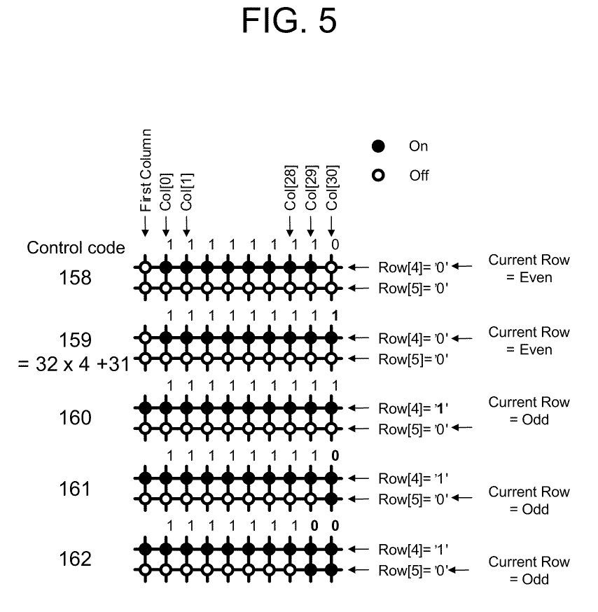

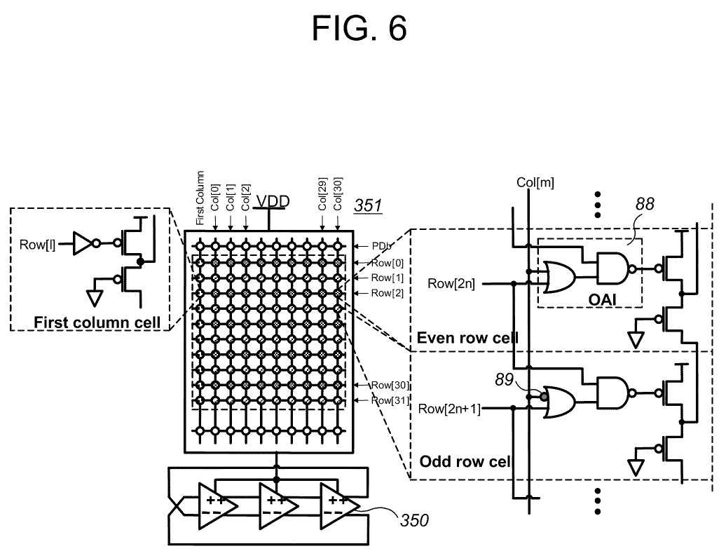

FIG. 5 and FIG. 6 are schematic diagrams illustrating the algorithm of the switching matrix based glitch-free segment thermometer converter and the implementing method thereof in accordance with the present invention. Referring to FIG. 6, we can see that we can prevent the situation wherein all the LSB bits simultaneously change from “1111 . . . 1” to “00 . . . 0” when the MSB changes the state from 0 to 1 by inverting the column values of the odd-numbered MSB rows and feeding them as well as the non-inverted column values of the even-numbered MSB rows to the logic circuits.

Referring to FIG. 6 again for further explanation, we can see that the system comprises an OAI (OR-AND-INVERT; 88) circuit for even-numbered row cell wherein the switch turns “ON” by feeding the current row (2n) and the column (m) to the OR gate when the column code is “1”. In the meanwhile, we make sure that the switch turns “ON” by feeding the inverted columns of the OR-AND-INVERT (89) for odd-numbered row cell when column code is “0”. As a consequence, we make sure that the switch can change the state one by one.

The variable resistance switching matrix which comprises the DCO in accordance with the present invention includes additional cells for controlling the initial oscillation at the moment of power-up as well as 2^{m/2}×2^{m/2} cells, which are made of PMOS gate-controlled resistance matrix, for frequency tuning. The additional cells are made of gate-grounded PMOS transistors. The gates of the first column cells are fed with the inverted row data while the gates of the even-numbered row cells are fed with OR operated data of row data and column data, and the inverted OAI data. The gates of the odd-numbered row cells are fed with OR operated data of the inverted row data and column data, and the NOT-OAI (not-or-and-invert) data of the preceding row.

As aforementioned, the present invention has a feature of controlling the input current by varying the resistance of each resistor of the 32 bit×32 bit switching matrix which is connected to the power supply. We should note, however, that the rate of the current change is 100% when the current level switches from level 1 to level 2, while the rate of current change is only 0.1% when the current level switches from level 1023 to level 1024. Consequently, we need an equalization process for the overall current change.

In order to equalize the rate of current change between the upper-part switches and the lower-part switches in the resistance switching matrix, we add a variable resistance element (91′) in the array of a first PMOS transistor (92) and insert a second PMOS transistor (92) as a vertical resistance (92′) between the rows.

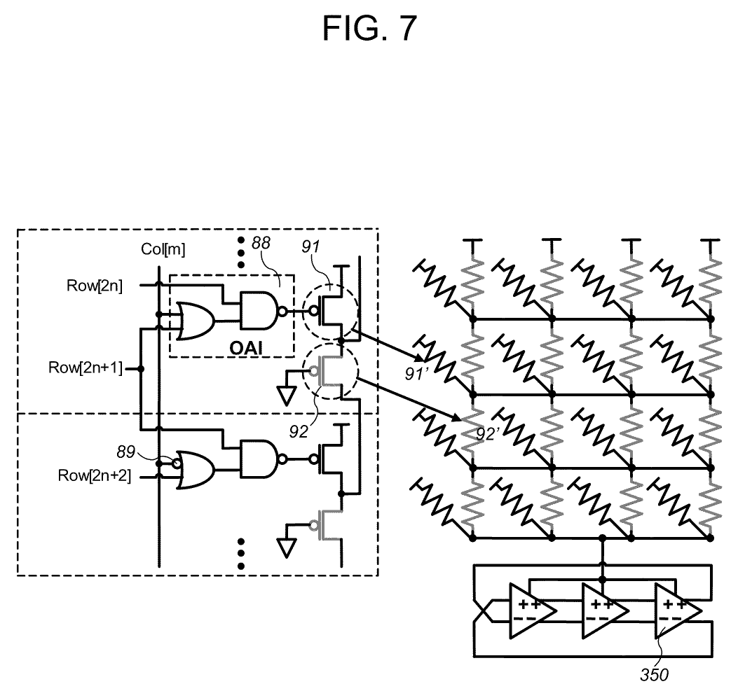

FIG. 7 is a schematic diagram illustrating the configuration of the present invention wherein a second PMOS transistor (92) is inserted between the rows in addition to a first PMOS transistor (91) constituting the resistance switching matrix in an effort to equalize the amount of current change for each entry of the switching matrix.

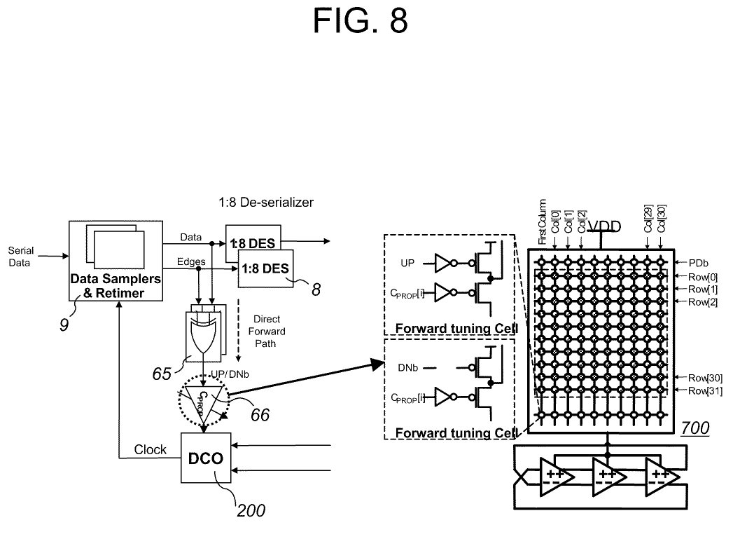

FIG. 8 is a schematic diagram illustrating the building block constituting the direct forward path of the CDR in accordance with the invention. As afore-mentioned, the CDR of the present invention can tune the frequency of the DCO (200) by the following mechanism. The 1:8 de-serializer (8) feeds 8-bit data and edge information to control logic circuits (not shown in FIG. 8) which produces the 32+32 bit thermometer code as an output. Here, we have a 2-bit forward path between a phase detector (9) and DCO (200) for the stability of the feed-back loop.

The present invention has a feature of employing a charge pump PLL instead of using the conventional RC loop filter and charge pump circuit. Digitally controlled oscillator (DCO) in FIG. 8 can be implemented with a 3-stage inverter chain and the power supply can be implemented by digitally controlled resistors. As a preferred embodiment, the digital-controlled variable resistors can be made of 1024 PMOS transistor switches for frequency tuning, and 96 switches can be utilized for controlling the initial oscillation when powered up.

DCO (200) of the present invention has an additional tuning cell as a 2-bit direct path which receives the up/down signal from the phase detector (9). The tuning cell (700) of the direct forward path directly controls the frequency of the DCO eight times faster than the integral path (not shown) and provides the stability of the circuit.

In this embodiment, digitally controlled oscillator (200) makes the UP/DOWN signals control on and off in 1 through to 8 tuning cells depending on the value of CPROP. From the perspective of bandwidth and stability of the loop circuits, it is desirable to have an equalized tuning step (fₛₜₑₚ=fₙ+1/fₙ) for the digitally controlled oscillator (200), if possible. The equalization of the frequency tuning step implies that the frequency increases as an exponential manner, fₙ=f₀fₛₜₑₚⁿ, as the digital-controlled codes increase.

To achieve the equalization, the inventors provide a switching matrix which is constituted by additional PMOS transistors inserted between the rows. As a consequence, we can make the frequency be tuned in an exponential manner in response to the change of the row code.

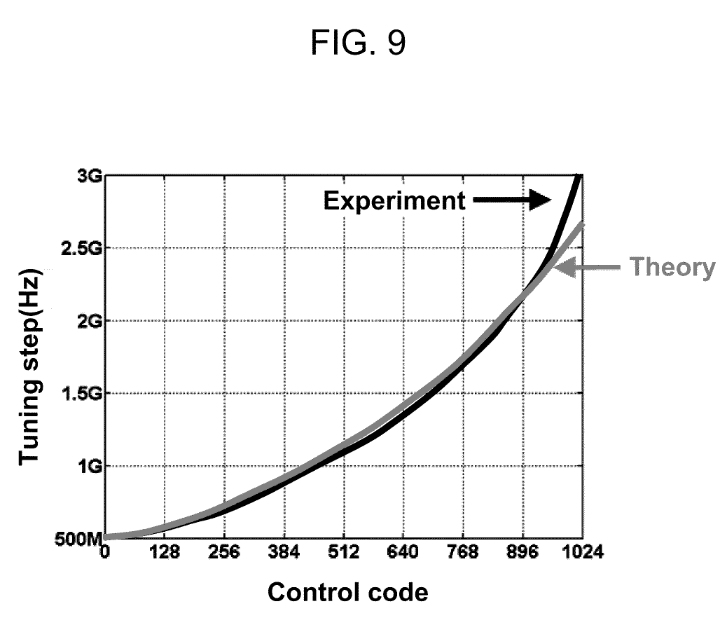

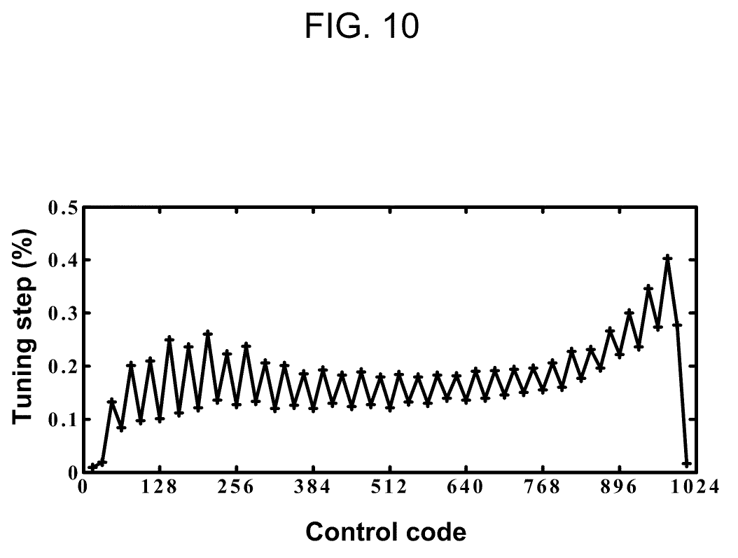

FIG. 9 and FIG. 10 are diagrams illustrating the frequency tuning experiments when additional resistors are inserted between the rows in the switching matrix. Referring to FIG. 9, we can see that Digital Controlled Oscillator which comprises the Clock Data Recovery in accordance with the invention exhibits an ideal behavior as the digital code switches from level 0 to level 1024. In addition, FIG. 10 demonstrates that the frequency changes in an equalized manner in response to the level change of the control code.

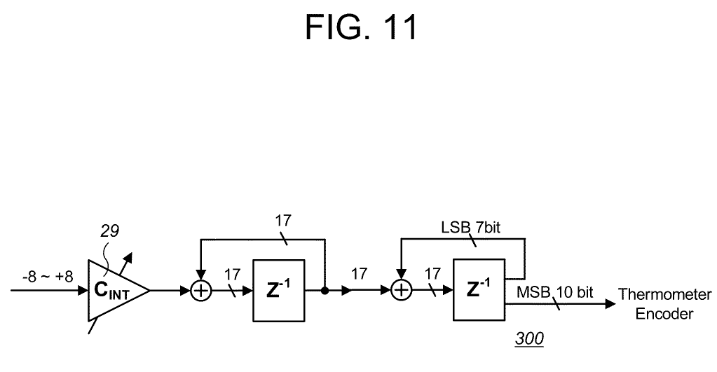

FIG. 11 is a schematic diagram illustrating an integral path which constitutes a block of the CDR in accordance with a preferred embodiment of the invention. FIG. 11 demonstrates the operating principle of the fully synthesized control logic (600), which comprises an UP/DN signal generators (28), an IIR filter (29), a sigma-delta modulator (300), a binary to segment thermometer converter (400), and frequency detector (31).

The UP/DN signal generator (28) generates the up/down signals in the range of −8 to +8 levels out of the 16-bit signal which are transmitted by the 1:8 de-serializer (8) of the preceding block. Further, the IIR Filter (29) generates a 17-bit frequency code by integrating the input phase information in the range of −8˜+8 levels. Since it is technically difficult to hardware-implement a digitally controlled oscillator (200) having a resolution power of 17 bits, it is more preferable to generate a frequency control code with MSB 10 bits by dithering LSB 7 bits out of a total of 17 bits through employing a 1^{st}-order Σ^{Δ} modulator (300). The dithering algorithm allows us to generate a code which can control the decimals by utilizing the LSB 7 bits in case when there is no up/down change in the input serial data.

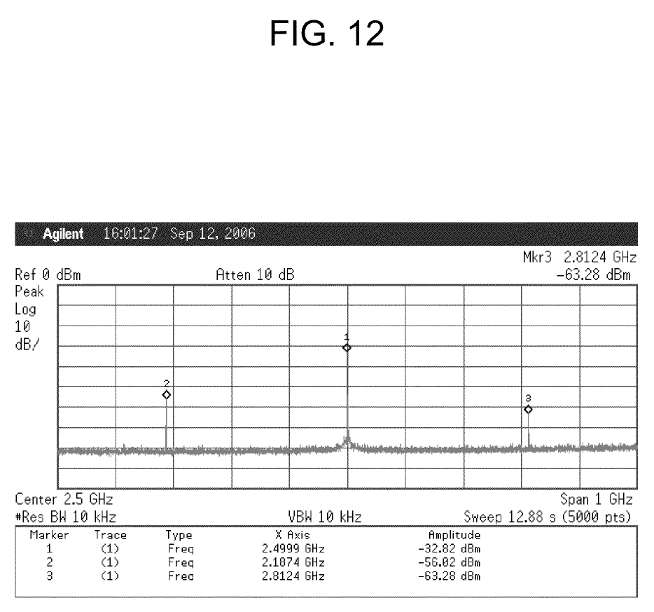

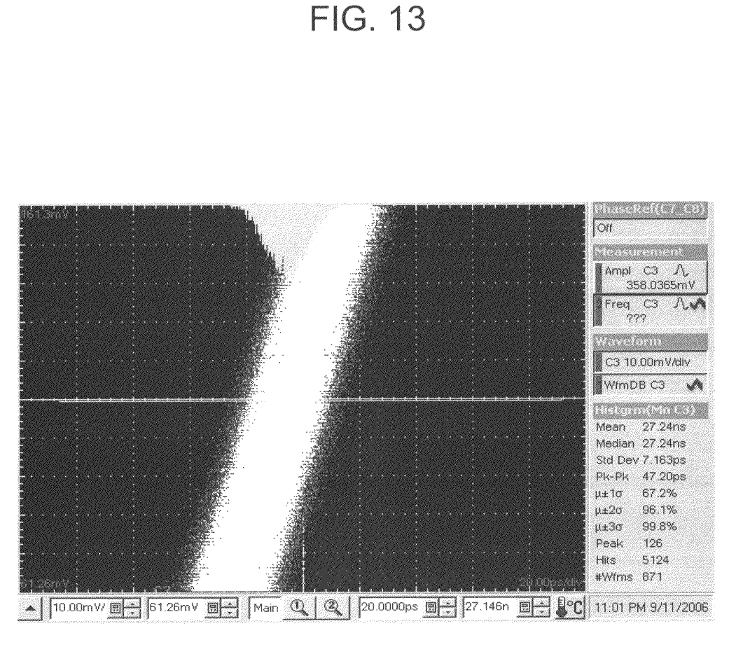

FIG. 12 and FIG. 13 are schematic diagrams illustrating an example when the clock is recovered by utilizing the CDR in accordance with the invention. Referring to FIG. 12 and FIG. 13, we can observe that the resolution power of the center frequency is 8 ppm, which is due to the 17-bit resolution power of the IIR. Referring to FIG. 12, we can see that the dithering frequency locates at 312.5 MHz as a spur of the dithering, which is coincident with the fact that the dithering logic circuit operates with a speed which is 8 time slower than the input serial data, 2.5 GBPS.

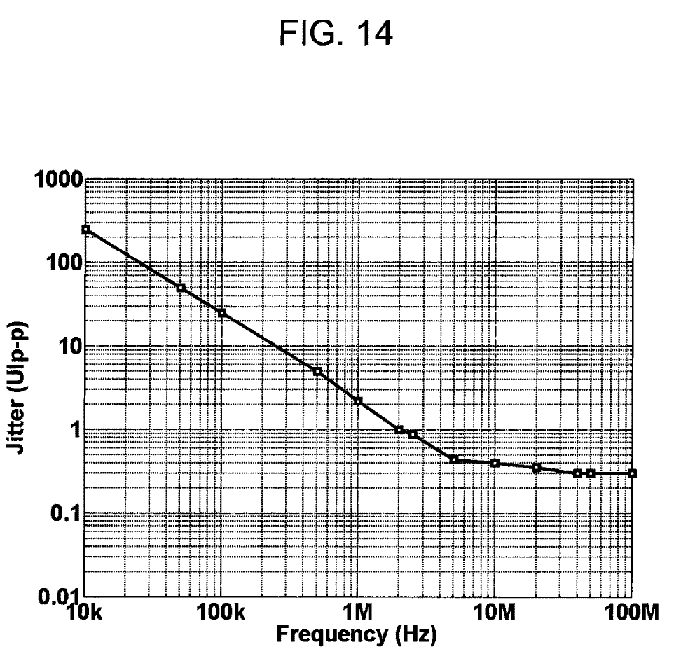

The quantization effect is shown as jitters in the time-domain. FIG. 14 illustrates the (2³¹−1) PRBS pattern at 2.5 GBPS under the 1.2 V power supply. Referring to FIG. 11, we see that the RMS jitter is 7.2 PS while the peak-to-peak jitter is 47.2 PS, which is sufficient for the application as a GBPS transceiver.

The aforementioned somewhat widely improves the characteristics and technical advantages of the present invention so that the scope of the invention to be described later can be more clearly understood. The additional characteristics and technical advantages that constitute the scope of the present invention will be described below. The features that the disclosed concept and specific embodiments of the present invention can be instantly used as a basis designing or correcting other structure for accomplishing a similar object with the present invention should be recognized by those skilled in the art.

Further, it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

The present invention provides a solution to implement a fill digital CDR with sub-100 nanometer semiconductor technology by curing the leakage problem of the current source comprising the traditional PLL-type VCO. Furthermore, the present invention overcomes the jitter problem due to the leakage current of the conventional analog PLL by utilizing the digital filter and DCO for frequency tuning, which also makes it possible to program the filter coefficient even if the design rule becomes tight due to scale-down.

In addition, the present invention separates the direct forward path with the integral path in order to compensate for the slow operating speed of the digital filter wherein the integral path can be operated with a sub-clock rate. The present invention also resolves the jitter problem which is due to the quantization as well as the equalization of the frequency tuning. The CDR according to the invention can achieve a GBPS data transmission rate for 1.0 V power supply voltage.

1. Clock Data Recovery (CDR) which restores data and clock from the serial data stream, comprising:
a phase detector which produces a digital sequence of data and a digital sequence of edge by sampling the serial data stream with a clock;
a de-serializer which transforms the digital sequences of data and edge, which are outputs of the phase detector, into n-bit bus through serial-to-parallel converting the digital sequences at the ratio of 1:n;
a digitally controlled oscillator (DCO) being implemented by a multi-stage chain of inverters having a variable resistance switching matrix wherein the resistance of each element of the variable resistance switching matrix is varied in such a way that the supply current being fed to each inverter is controlled in pursuant to a digital control code, and thereby producing a clock whose oscillation frequency is updated and fed to the phase detector;
a digital synthesis control logic circuit which generates a thermometer-code-type digital control code out of the n-bit data and n-bit edge from the de-serializer wherein the thermometer-code-type digital control code is fed to the DCO; and
a 2-bit direct forward path which directly controls the frequency of the clock being produced by the DCO with an operating speed which is faster than the digital synthesis control logic circuit by n times;
wherein the phase detector, the de-serializer, the DCO, the digital synthesis control logic circuit, and the 2-bit direct forward path are implemented by all-digital circuits.

2. The CDR as set forth in claim 1 wherein the digital synthesis control logic circuit comprises;
an UP/DN signal generator which delivers a command either for raising or for lowering the oscillation frequency in the range of −n to +n levels out of the n-bit data and n-bit edge from the de-serializer;
an IIR digital filter which generates an (m+k)-bit digital code through integrating the UP/DN signal from the UP/DN signal generator;
a first-order sigma-delta modulator which dithers LSB k bits and produces an MSB m-bit digital code out of the (m+k) bits from the IIR digital filter for the effect of (m+k) resolution power;
a binary-to-segment thermometer converter converting a total of 2^{m} frequency tuning levels, which is corresponding to the m-bit code from the first-order sigma-delta modulator, into a [2^{m/2}+(2^{m/2}−1)]-bit thermometer code, which is thereby delivered to the routing wires of the rows and columns of the variable resistance switching matrix constituting the DCO; and
a frequency detector which enforces a digital code, which is corresponding to a reference frequency, when the error between the clock frequency and the reference frequency goes beyond the threshold.

3. The CDR as set forth in claim 1, characterized in that the variable resistance switching matrix comprises 2^{m/2}×2^{m/2} cells for frequency tuning and additional cells for initialization of frequency oscillation at power-up, wherein the cells at the first column are set “ON” when the corresponding row code is “1”, the cells of the even-numbered rows being set “ON” when the corresponding column code is “1”, and the cells of the odd-numbered rows being set “ON” when the corresponding column code is “0”.

4. The CDR as set forth in claim 1, characterized in that that the variable resistance switching matrix comprises 2^{m/2}×2^{m/2} cells for frequency tuning and additional cells for initialization of frequency oscillation at power-up, wherein those cells are implemented by PMOS gate-controlled resistance matrix, additional PMOS gate-grounded resistors being inserted between the rows.

5. The CDR as set forth in claim 1, characterized in that the variable resistance switching matrix comprises 2^{m/2}×2^{m/2} cells for frequency tuning and additional cells for initialization of frequency oscillation at power-up, wherein those cells are implemented by PMOS gate-controlled resistance matrix, additional PMOS gate-grounded resistors being inserted between the rows, the inverted row data being fed to the gates of the cells of the first column, OAI (or-and-invert) data—OR operating the row data and the column data which is followed by AND operation of the OR-operating data and the preceding row data, and then followed by NOT operation, being fed to the gates of the cells of the even-numbered rows, NOT-OAI (not-or-and-invert) data—OR operating the inverted row data and the inverted column data which is followed by AND operation of the OR-operating data and the preceding row data, and then followed by NOT operation, being fed to the gates of the cells of the odd-numbered rows cells.

6. The CDR as set forth in claim 1, characterized in that the direct forward path generates an UP/DN signal through XOR-operating the data and the edge of the phase detector, providing the UP/DN signal to the gates of 2^{m/2} cells which constitutes the lowest row of the variable resistance switching matrix of the DCO, and thereby tuning the frequency of the DCO with a speed which is n times faster than the digital synthesis control logic circuits.

7. (canceled)

8. A transceiver comprising a Clock Data Recovery (CDR), said transceiver and CDR comprising:
a phase detector which produces a digital sequence of data and a digital sequence of edge by sampling the serial data stream with a clock;
a de-serializer which transforms the digital sequences of data and edge, which are outputs of the phase detector, into n-bit bus through serial-to-parallel converting the digital sequences at the ratio of 1:n;
a digitally controlled oscillator (DCO) being implemented by a multi-stage chain of inverters having a variable resistance switching matrix wherein the resistance of each element of the variable resistance switching matrix is varied in such a way that the supply current being fed to each inverter is controlled in pursuant to a digital control code, and thereby producing a clock whose oscillation frequency is updated and fed to the phase detector;
a digital synthesis control logic circuit which generates a thermometer-code-type digital control code out of the n-bit data and n-bit edge from the de-serializer wherein the thermometer-code-type digital control code is fed to the DCO; and
a 2-bit direct forward path which directly controls the frequency of the clock being produced by the DCO with an operating speed which is faster than the digital synthesis control logic circuit by n times;
wherein the phase detector, the de-serializer, the DCO, the digital synthesis control logic circuit, and the 2-bit direct forward path are implemented by all-digital circuits; and
wherein the transceiver sends and/or receives the serial data stream.
